(19) United States
(12) Patent Application Publication
(10) Pub. No.: US 2023/0170425 A1
(43) Pub. Date: Jun. 1, 2023

(54) OPTOELECTRONIC SEMICONDUCTOR STRUCTURE

(71) Applicant: RAYNERGY TEK INCORPORATION, HSINCHU (TW)

(72) Inventors: YI-MING CHANG, Hsinchu (TW); JHAO-LIN WU, Hsinchu (TW); ZI-WAN SUN, Hsinchu (TW)

(21) Appl. No.: 17/662,944

(22) Filed: May 11, 2022

(30) Foreign Application Priority Data
Dec. 1, 2021 (TW) 110144914

(51) Int. Cl. H01L 31/0224; H01L 31/10; H01L 31/0352; H01L 51/44

(52) U.S. Cl. CPC H01L 31/022408; H01L 31/10; H01L 31/035272; H01L 51/441

(57) ABSTRACT

An optoelectronic semiconductor structure is revealed. The optoelectronic semiconductor structure includes a substrate, a first electrode, an electrode contact, a semiconductor layer, and a second electrode. After a photoactive layer of the semiconductor structure absorbs energy from a light source to generate an exciton, the exciton dissociates into a first carrier and a second carrier. The first carrier is transferred to the first electrode through the first interface layer while the second carrier is transferred from the second electrode to the electrode contact directly by a tunneling effect.

### TECHNICAL FIELD

The present invention relates to a semiconductor structure, especially to an optoelectronic semiconductor structure.

### BACKGROUND

CIS (complementary metal oxide semiconductor image sensors) and thin-film transistor (TFT)-based image sensors are two common technologies for the image sensor market. The image sensor includes photodetector (PD) in combination with CMOS or TFT readout integrated circuits (ROICs) on a lower layer. Photodiodes are the predominant types of photodetectors (PD) and the most common materials used to make the photodiode is silicon.

In recent years, photodiodes made of next generation materials such as organic photodetectors, quantum dot photodetectors, and perovskite photodetectors have been developed in order to meet more requirements including higher sensitivity, broader wavelength range, and price-performance ratio in applications. These PDs made from new materials are also different from conventional silicon PD in structure and are produced by multiple layers stacked from the bottom to the top.

In the PD produced by the above stacking way, the first electrode and the second electrode are unable to contact each other in order to form a complete circuit, otherwise short circuit will occur. Yet such type of PD is unable to be produced by a pattern definition method such as shadow-mask evaporation and direct printing.

After deposition of coatings on the whole substrate of the PD, a connection portion of an external wire needs to be removed to achieve a good ohmic contact between an electrode of the PD and the external wire. Otherwise a series resistance of the photodetector is increased and further affecting generation of a photocurrent after the PD integrated with thin-film transistor (TFT) array panel or complementary metal— oxide—semiconductor (CMOS) array panel.

After deposition of coatings on the whole substrate, via holes are generated by a step and then the second electrode is connected with a contact pad on the readout circuit to form a complete diode circuit.

In order to generate via holes on a surface layer of the substrate after deposition of the coatings, optical lithography is carried out after coating of photoactive material and interface layer material.

The steps involved in optical lithography include application of a photoresist layer (positive photoresist or negative photoresist) on the substrate, exposure (an excimer laser operated in the ultraviolet spectra region) and dissolution of the photoresist in a developer (developing). Specific light waves illuminate a mask placed over the substrate and the photoresist is exposed to the light selectively. Then the photoresist on the radiated area is dissolved in the developer.

Then a pattern on the mask is created on the photoresist, and a etching process is conducted accordingly. After completing the above steps, the last step of the photolithography-photoresist removal is performed and then deposition of a second electrode is carried out.

The compatibility among photoresists materials, photoresist materials, and interface materials (such as miscibility, chemical reactions, and photoresist residuals) and parameter tuning and plasma selection used for etching and specific to materials for the respective layers all get the entire process more complicated.

Moreover, the steps involved in the photolithography such as coating, deposition, generation of via holes, and the following deposition of the second electrode are is cumbersome, time consuming, and costly. For diode components in which the photoactive layer and interface layer are unable to be formed directly by the pattern definition method such as shadow-mask evaporation and direct printing, the above process is not feasible.

Thus there is room for improvement and there is a need to provide an optoelectronic semiconductor structure which forms a complete diode circuit without generation of via holes by steps of photoresist coating, soft bake, exposure, hard bake, developing, etching and photoresist removal.

### SUMMARY OF THE INVENTION

Therefore, it is a primary object of the present invention to provide an optoelectronic semiconductor structure in which currents injected from electrodes go into diodes by tunneling even with the existence of an interface layer and a photoactive layer therebetween (without via hole) when certain conditions such as specifications of materials including characteristics, thickness are met. Thus components work normally without having electrical loss.

In order to achieve the above object, an optoelectronic semiconductor structure according to the present invention includes a substrate, a first electrode disposed over the substrate, an electrode contact arranged over the substrate and located at one side of the first electrode, a semiconductor layer set over the first electrode and the electrode contact and provided with a first interface layer and a photoactive layer, and a second electrode disposed over and covering the semiconductor layer. The photoactive layer is arranged over and covering the first interface layer while one side of the first interface layer is disposed over and covering the first electrode and the electrode contact. After the photoactive layer absorbs energy from a light source to generate an exciton, the exciton is separated into a first carrier and a second carrier. The first carrier is transferred to the first electrode through the first interface layer while the second carrier is transferred from the second electrode to the electrode contact directly by a tunneling effect.

Preferably, the substrate can be made of silicon, polyimide, glass, polyethylene naphthalate, polyethylene terephthalate, sapphire, quartz, or ceramic. As to the first electrode, it is made of metal oxides, metals, or alloys.

Preferably, materials for the electrode contact include metal oxides, metals, and alloys.

Preferably, the semiconductor layer surrounds the first electrode and the electrode contact.

Preferably, the first interface layer is made of metal oxides, metallic compounds, inorganic semiconductor thin film, carbon-based thin film, organic semiconductor, and organic insulation materials and having a first thickness is 1 nm to 99 nm.

Preferably, an energy gap of the photoactive layer is 1.1 eV to 2 eV.

Preferably, the photoactive layer has a second thickness ranging from 1 nm to 2000 nm.

Preferably, the second electrode is made of metal oxides, metals, conducting polymers, carbon-based conductors, metallic compounds and combinations of the above materials in a form of a conductive thin film.

Preferably, the semiconductor layer further includes a second interface layer which is mounted over the photoactive layer and the photoactive layer is clipped between the first interface layer and the second interface layer.

Preferably, the second interface layer can be made of metal oxides, metallic compounds, inorganic semiconductor thin film, carbon-based thin film, organic semiconductor, and organic insulation materials and having a third thickness is 1 nm to 99 nm.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1A is a schematic drawing showing structure of an embodiment according to the present invention;

FIG. 1B is a schematic drawing showing structure of a prior art according to the present invention;

FIG. 2 is a schematic drawing showing current tunneling effect in an embodiment according to the present invention;

FIG. 3 is a schematic drawing showing structure of another embodiment according to the present invention;

FIG. 4 is a schematic drawing showing a relationship between a second thickness and a dark-current of an embodiment according to the present invention;

FIG. 5 is a schematic drawing showing a relationship between a second thickness and a photo-current of an embodiment according to the present invention;

FIG. 6 is a schematic drawing showing a relationship between a second thickness and external quantum efficiency of an embodiment according to the present invention;

FIG. 7 is a schematic drawing showing a relationship between a second thickness and external quantum efficiency of an embodiment according to the present invention;

FIG. 8 is a schematic drawing showing a relationship between a second thickness and external quantum efficiency of an embodiment according to the present invention;

### DETAILED DESCRIPTION

In order to learn features and functions of the present invention, please refer to the following embodiments and related drawings.

In order to generate via holes on a surface layer of the substrate after deposition of the coatings, optical lithography or a laser process is carried out after coating of photoactive material and interface layer material. Take optical lithography as an example, deposition of a second electrode is carried out only after the steps of photoresist coating, soft bake, exposure, hard bake, developing, etching and photoresist removal. Moreover, the steps of coating, deposition, generation of via holes, and the following deposition of the second electrode are cumbersome, time consuming, and costly. As to diode components in which a photoactive layer and an interface layer are unable to be produced directly by the pattern definition method such as shadow-mask evaporation and direct printing, they can't be manufactured by such method.

In the present invention, through changes in properties and thickness of materials, currents injected from electrodes can enter the diodes by tunneling even with the existence of a photoactive layer and an interface layer therebetween (without via holes) to make components work normally without having electrical loss. Moreover, photolithography performed in the following process for etching and patterning semiconductor materials is no more required. Thus the present invention can be applied to manufacturing of diode components which are unable to be produced directly by pattern definition method.

Please refer to the following embodiments with reference to the related figures. There are various implementations of the present invention, not intended to limit the present invention.

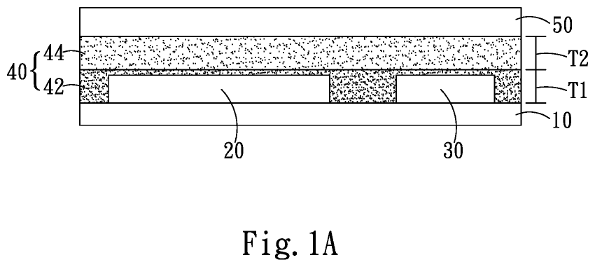

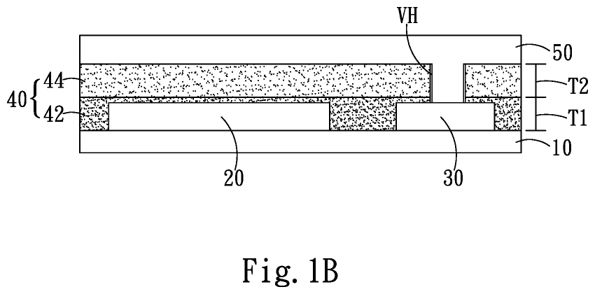

Refer to FIG. 1A, an optoelectronic semiconductor structure according to the present invention includes a substrate 10, a first electrode 20, an electrode contact 30, a semiconductor layer 40, and a second electrode 50.

In this embodiment, the first electrode 20 is disposed over the substrate 10 while the electrode contact 30 is also arranged over the substrate 10 and located at one side of the first electrode 20. The substrate 10 can be made of silicon, polyimide, glass, polyethylene naphthalate, polyethylene terephthalate, sapphire, quartz, or ceramic. Materials for the first electrode 20 and the electrode contact 30 include metal oxides, metals, and alloys.

In this embodiment, the semiconductor layer 40 which includes a first interface layer 42 and a photoactive layer 44 is mounted over the first electrode 20 and the electrode contact 30. The first interface layer 42 is made of metal oxides, metallic compounds, inorganic semiconductor thin film, carbon-based thin film, organic semiconductor, and organic insulation materials and having a first thickness T1 which is ranging from 1 nm to 99 nm. The first thickness T1 is smaller than 100 nm and 80 nm is preferred. In another preferred embodiment, the first thickness T1 is from 1 nm to smaller than 80 nm.

Still refer to FIG. 1A, the semiconductor layer 40 surrounds the first electrode 20 and the electrode contact 30. As shown in FIG. 1A, one side of the first interface layer 42 of the semiconductor layer 40 is disposed on and covering the first electrode 20 and the electrode contact 30 so that gaps around the first electrode 20 and the electrode contact 30 are filled with the semiconductor layer 40.

In the embodiment shown in FIG. 1A, the photoactive layer 44 has a second thickness T2 which is ranging from 1 nm to 2000 nm while 300-1000 nm is preferred.

An energy gap of the photoactive layer 44 is 1.1 eV to 2 eV while 2 eV is preferred. The above energy gap is a difference between energy of conduction band and valance band of semiconductors or insulators. When the energy gap is fulfilled, carriers are transferred through the semiconductor layer 40 by tunneling and this is so-called tunneling effect.

In this embodiment, the second electrode 50 is disposed over and covering the semiconductor layer 40 and made of metal oxides, metals, conducting polymers, carbon-based conductors, metallic compounds and combinations of the above materials in a form of a conductive thin film.

Refer to FIG. 1B, a structure of conventional semiconductor is revealed. A shown in FIG. 1B, a via hole VH is formed on the semiconductor layer 40 and located between the second electrode 50 and the electrode contact 30 by steps of a photolithography process including photoresist coating, soft bake, exposure, hard bake, developing, etching, photoresist removal. Thus the second electrode 50 can be deposited to the electrode contact 30 through the via hole VH. However, such process is cumbersome, time consuming, and costly. For diode components in which the semiconductor layer 40 is unable to be produced by the pattern definition method, the process is useless.

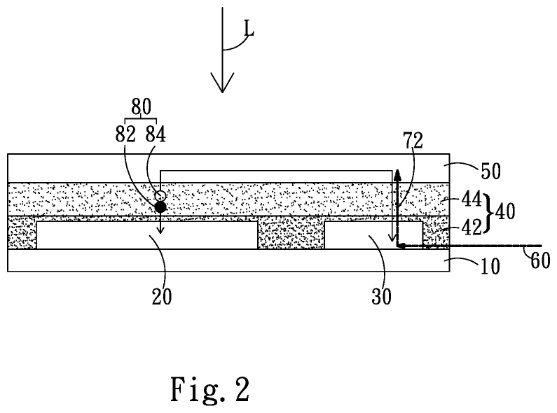

Refer to FIG. 2, a schematic drawing showing current tunneling effect in an embodiment of the present invention is revealed. When the photoactive layer 44 absorbs energy from a light source L to generate an exciton 80, the exciton 80 is separated into a first carrier 82 and a second carrier 84. The first carrier 82 is transferred to the first electrode 20 through the first interface layer 42 while the second carrier 84 is transferred from the second electrode 50 to the electrode contact 30 directly by a tunneling effect. By the tunneling effect, the second carrier 84 is directly penetrating the semiconductor layer 40 and then entering the electrode contact 30. No VH is required for transferring the second carrier 84. The semiconductor structure mentioned above obtains the same amount of power as the conventional semiconductor with VH since the tunneling effect causes no electrical loss of the carrier 84. Moreover, processing process is simplified and processing time is reduced.

When a current 60 is provided to the electrode contact 30, the tunneling effect occurs in the semiconductor. By a first tunnel 72 which is generated due to the tunneling effect and penetrating the semiconductor layer 40, the current 60 is supplied from the electrode contact 30 to the second electrode 50. Then the second carrier 84 is passed through the second electrode 50 and the first tunnel 72 and then transferred to the electrode contact 30.

The above tunneling effect means that the thickness of the semiconductor layer is relatively thin so that charges can pass through the semiconductor layer directly. And a resistance generated by the thickness is so minimal in the whole component that the operation and performance of the components will not be affected.

Still refer to FIG. 2, in this embodiment, due to no via hole, the carriers generated can still be transferred from the second electrode 50 to the electrode contact 30 under existence of the semiconductor layer 40 with certain thickness and then working together with the first electrode 20 to form a diode circuit. In the conventional structure (shown in FIG. 1B), a VH (via hole) is formed at the semiconductor layer 40 between the second electrode 50 and the electrode contact 30 by steps of a photolithography process including photoresist coating, soft bake, exposure, hard bake, developing, etching, photoresist removal. Thus the second electrode 50 can be deposited to the electrode contact 30 through the VH. However, such process is cumbersome, time consuming, and costly. By contrast, the present embodiment provides a complete circuit without etching of via holes. The multiple steps of the complicated process are omitted so that both cost and processing time are reduced.

The embodiment can be applied to image sensors available now including two common technologies, CMOS image sensors and TFT-based image sensors.

The principle of the image sensors mentioned above is based on photodetectors (PD) which converts light capture by camera lenses into digital data in order to construct visible images. In other words, the photodetector is disposed over CMOS or TFT. When light from an external light source reaches the photodetector over CMOS or TFT, the CMOS or TFT absorbs light energy to generate electron-hole pairs.

Electrons generated during the above process are transformed into a voltage by floating diffusion. Then the voltage is transferred to an Analog-to-Digital converter (ADC) and converted into digital data. At last a processor is used to convert the digital data into visible images.

For products with higher requirements for image dynamics and sensitivity such as lens and biochips, CMOS image sensors are selected. While being applied to large area image sensors such as X-ray images and large area fingerprint recognition or vein recognition of human body, TFT-based image sensors are used.

The PD improved by the present invention can be applied to CMOS image sensors or TFT-based image sensors. The steps of the processing process of the PD are reduced so that processing time of PD is shortened and processing cost is reduced.

Back to FIG. 1B, optical lithography is used in conventional opto-semiconductor (PD mentioned above) fabrication. After confirming positions and areas going to be patterned, positive photoresist or negative photoresist is used and deposited on a thin-film-layer structure going to be patterned. Then several steps including exposure, developing, etching, photoresist removal . . . and so on are carried out at selected positions to remove thin-film-layer structure of an area of the second electrode 50. Thus the VH (via hole) in FIG. 1B is obtained. The deposition of the second electrode 50 can be only performed after formation of the penetrating VH. Thereby the second electrode 50 and the electrode contact 30 are in contract with each other to form the diode circuit.

The optical lithography mentioned above is not only having complicated and complex process, but also having a low fault tolerance rate in the process. The overall processing time of the optical lithography is long due to more steps in the process. These all lead to the complicated and expensive process of manufacturing optoelectronic semiconductors.

In a preferred embodiment, the thickness of the semiconductor layer 40 is adjusted to be 1 nm to 2000 nm. Thus the tunneling effect occurs due to changes in the thickness and this result in a complete diode circuit.

The complete circuit is provided without formation of the via holes in the semiconductor layer 40 so that the complicated processing process is saved and both cost and processing time are further reduced.

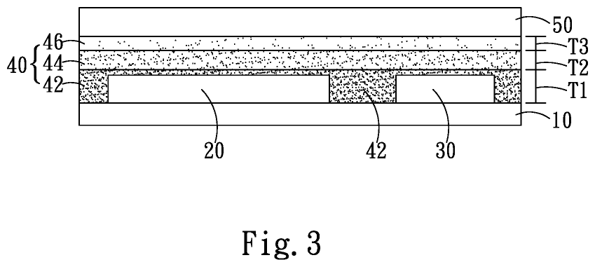

Refer to FIG. 3, another embodiment is revealed. The structure of this embodiment is about the same as the above one. The difference of this embodiment is in that this embodiment further includes a second interface layer 46. As shown in FIG. 3, the semiconductor layer 40 further includes the second interface layer 46 which is arranged over the photoactive layer 44 so that the photoactive layer 44 is clipped between the first interface layer 42 and the second interface layer 46.

In this embodiment, the second interface layer 46 is made of molybdenum trioxide (MoO₃) and having a third thickness T3 which is 1 nm to 99 nm while 80 nm is preferred. In another preferred embodiment, the third thickness T3 is smaller than 80 nm.

Moreover, the total thickness of the first interface layer 42 and the second interface layer 46 is smaller than 100 nm when the semiconductor layer 40 includes the first interface layer 42 and the second interface layer 46 while 80 nm is preferred. In another embodiment, the total thickness is smaller than 80 inn.

Furthermore, one of technical features of the embodiment according to the present invention is that there is no via hole. After the photoactive layer 44 absorbs energy from the light source L to generate an exciton 80, a first carrier 82 and a second carrier 84 are separated from the exciton 80. The first carrier 82 is transferred to the first electrode 20 through the first interface layer 42 while the second carrier 86 is directly transferred from the second electrode 50 to the electrode contact 30 directly by the tunneling effect, without through the VH in the conventional structure. Thereby the component with the present structure works well and there is no electrical loss. The followings are experiments showing impact of changes in the second thickness T2.

The followings are experimental conditions of an experiment group B:

1. The second thickness T2 of the present optoelectronic semiconductor structure is adjusted into 300 nm, 500 nm, 1000 nm, 1500 nm, and 2000 nm respectively.
2. Without any hole.

The followings are experimental conditions of a control group A:

1. The second thickness T2 of the present optoelectronic semiconductor structure is adjusted into 300 nm, 500 nm, 1000 nm, 1500 nm, and 2000 nm respectively.
2. With holes.

The following is a comparison of the experimental group with the control group with dark current A/cm² (at-8 V), photo-current (at-8 V), and external quantum efficiency (EQE, −4 V and light source at 550 nm).

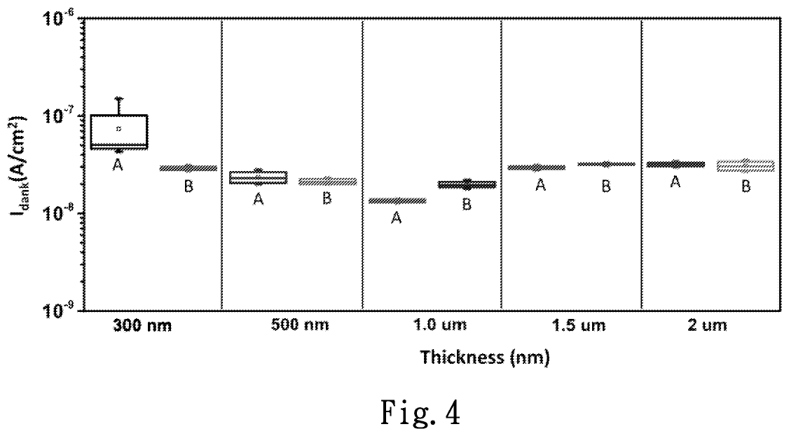

Refer to FIG. 4, a schematic drawing showing a relationship between changes in the second thickness and changes in a dark-current of an embodiment is revealed. As shown in the figure, the so-called Dark Current is a DC reverse current generated with negative bias potential when no outside photons are entering the semiconductors. The group A shown in FIG. 4 is the control group mentioned above while the group B is the above experimental group.

According to FIG. 4, it is learned that the dark current generated by the respective thickness of the experimental group (group B in FIG. 4) is similar to that of the control group (group A in FIG. 4). When the second thickness T2 of the photoactive layer 44 is 300 nm, the experimental group without VH has a lower dark current, which is better than the control group.

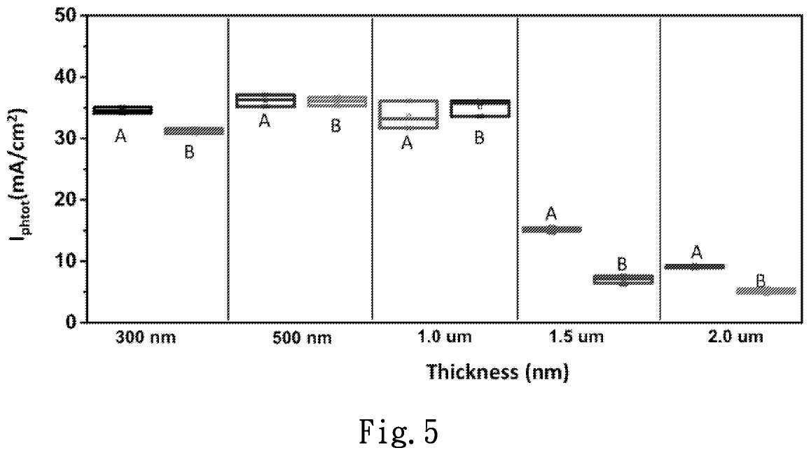

Refer to FIG. 5, a schematic drawing showing a relationship between changes in the second thickness and changes in a photo-current of an embodiment is revealed. In the present optoelectronic semiconductor structure, the second electrode 50 and the electrode contact 30 are in contact with each other by the tunneling effect. The group A in FIG. 5 is the control group mentioned above while the group B is the above experimental group.

Thereby the second thickness T2 certainly affects conduction of the photo-current. The larger the second thickness T2, the higher the resistance to the conduction of the photo-current. Thus the photo-current is significantly decreased when the second thickness T2 of the photoactive layer 44 is over 1500 nm.

The thickness of the photoactive layer 44 of the optoelectronic semiconductor structure according to the present invention is ranging from 1 nm-2000 nm. It is learned from FIG. 5 that the preferred second thickness T2 of the photoactive layer 44 is 1000 nm and able to be 1 nm to 1000 nm.

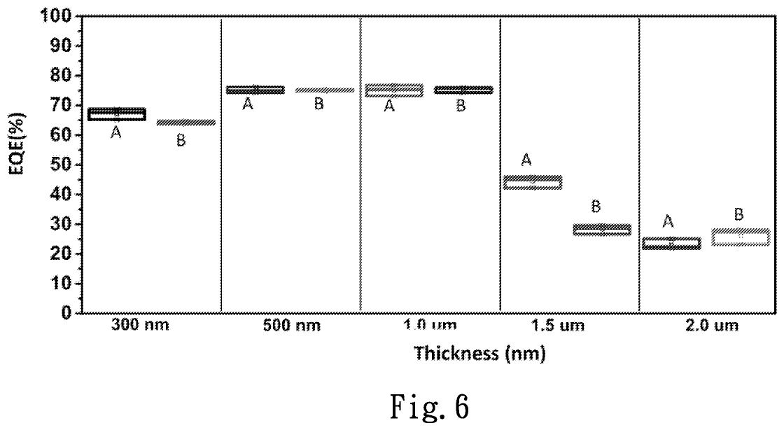

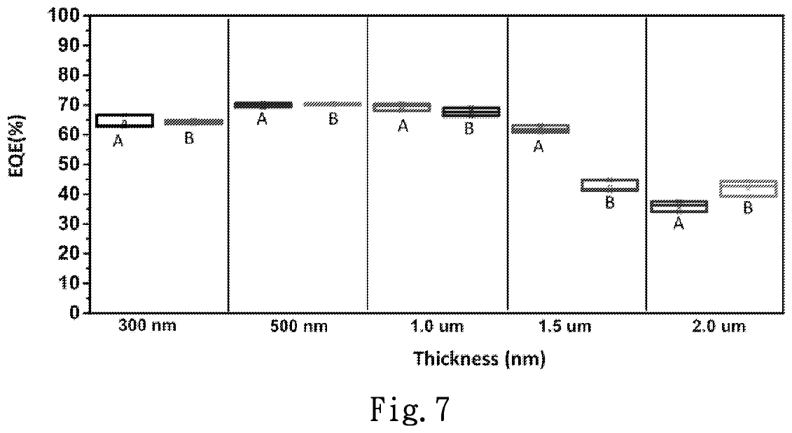

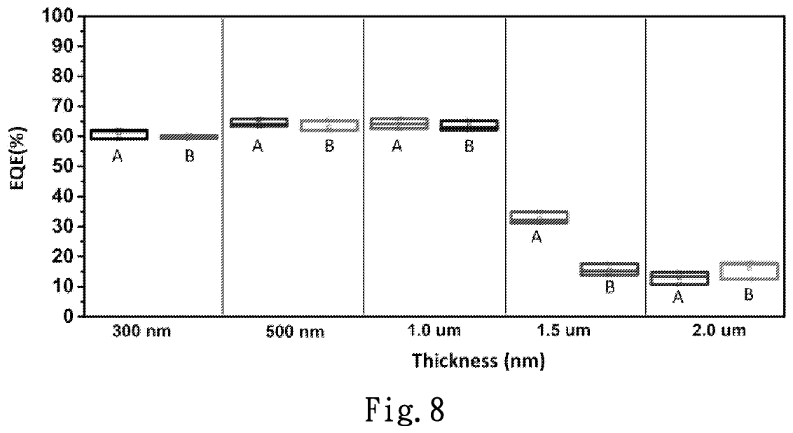

Refer to FIG. 6, FIG. 7, and FIG. 8, schematic drawings showing a relationship between changes in the second thickness and external quantum efficiency are revealed. As shown in the figures, the external quantum efficiency is a ratio of the number of carriers generated due to incident light and collected by optoelectronic semiconductor structure to the number of photons incident on the optoelectronic semiconductor structure. The group A labeled in FIG. 6, FIG. 7, and FIG. 8 is the control group mentioned above while the group B is the experimental group.

According to the results shown in FIG. 6, FIG. 7 and FIG. 8, it is learned that the relationship between the second thickness and external quantum efficiency has the same trend as the relationship between the second thickness and the photo-current mentioned above. The thickness T2 of the photoactive layer 44 of the optoelectronic semiconductor structure is ranging from 1 nm to 2000 nm while the preferred second thickness T2 of the photoactive layer 44 is 1000 nm.

In summary, the optoelectronic semiconductor structure in which the current from the electrode goes into the semiconductor layer by tunneling through changes in the thickness of the semiconductor layer even with the existence of the photoactive layer and the interface layer therebetween (without via hole). Thus the component works normally and no electrical loss is caused.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

What is claimed is:

1. An optoelectronic semiconductor structure comprising:
a substrate,
a first electrode disposed over the substrate,
an electrode contact arranged over the substrate and located at one side of the first electrode,
a semiconductor layer mounted over the first electrode and the electrode contact and provided with a first interface layer and a photoactive layer; the photoactive layer is arranged over and covering the first interface layer while one side of the first interface layer is disposed over and covering the first electrode and the electrode contact; and
a second electrode disposed over and covering the semiconductor layer;
wherein the photoactive layer absorbs energy from a light source to generate an exciton which is separated into a first carrier and a second carrier; the first carrier is transferred to the first electrode through the first interface layer while the second carrier is transferred from the second electrode to the electrode contact directly by a tunneling effect.

2. The optoelectronic semiconductor structure as claimed in claim 1, wherein the substrate is made of a material selected from the group consisting of silicon, polyimide, glass, polyethylene naphthalate, polyethylene terephthalate, sapphire, quartz, and ceramic; wherein the first electrode is made of a material selected from the group consisting of metal oxides, metals, and alloys.

3. The optoelectronic semiconductor structure as claimed in claim 1, wherein the electrode contact is made of a material selected from the group consisting of metal oxides, metals, and alloys.

4. The optoelectronic semiconductor structure as claimed in claim 1, wherein the semiconductor layer surrounds the first electrode and the electrode contact.

5. The optoelectronic semiconductor structure as claimed in claim 1, wherein the first interface layer is made of a material selected from the group consisting of metal oxides, metallic compounds, inorganic semiconductor thin film, carbon-based thin film, organic semiconductor, and organic insulation materials and having a first thickness is 1 nm to 99 nm.

6. The optoelectronic semiconductor structure as claimed in claim 1, wherein an energy gap of the photoactive layer is 1.1 eV to 2 eV.

7. The optoelectronic semiconductor structure as claimed in claim 1, wherein the photoactive layer has a second thickness ranging from 1 nm to 2000 nm.

8. The optoelectronic semiconductor structure as claimed in claim 1, wherein the second electrode is made of a material selected from the group consisting of metal oxides, metals, conducting polymers, carbon-based conductors, metallic compounds and combinations thereof in a form of a conductive thin film.

9. The optoelectronic semiconductor structure as claimed in claim 1, wherein the semiconductor layer further includes a second interface layer which is mounted over the photoactive layer; the photoactive layer is clipped between the first interface layer and the second interface layer.

10. The optoelectronic semiconductor structure as claimed in claim 9, wherein the second interface layer is made of a material selected from the group consisting of metal oxides, metallic compounds, inorganic semiconductor thin film, carbon-based thin film, organic semiconductor, and organic insulation materials and having a third thickness is 1 nm to 99 nm.
